(19) United States
(12) Patent Application Publication
(10) Pub. No.: US 2010/0061093 A1
(43) Pub. Date: Mar. 11, 2010

(54) ILLUMINATION DEVICES AND METHODS FOR MAKING THE SAME

(76) Inventors: Jeffrey R. Janssen, Ho Chi Minh City (VN); Michael A. Meis, Stillwater, MN (US); Patrick J. Hager, Woodbury, MN (US); Ellen O. Aeling, St. Paul, MN (US); Mark R. Wollner, Woodbury, MN (US)

Correspondence Address: 3M INNOVATIVE PROPERTIES COMPANY, PO BOX 33427, ST. PAUL, MN, 55133-3427, US

(21) Appl. No.: 11/908,295

(22) PCT Filed: Mar. 10, 2006
(86) PCT No.: PCT/US2006/008781

§ 371 Date: Jun. 24, 2009

Related U.S. Application Data
(60) Provisional application No. 60/661,088, filed on Mar. 12, 2005.

(51) Int. Cl. F21V 1/00; B05D 5/12; C23C 16/513; C25D 5/00

(52) U.S. Cl. 362/235; 427/66; 427/569; 205/80; 216/13

(57) ABSTRACT

The present disclosure is generally directed to illumination devices, and particularly directed to illumination devices utilizing light transmissive layers and methods for making the same. An illumination device and method for making the device are disclosed. The device, in particular, includes a substrate and conductive region disposed on the substrate. One or more light sources, such as LEDs, are disposed on a surface of the substrate and electrically coupled to the electrically conductive region for supply of electric current. The device also includes one or more light transmissive layers disposed on the substrate and the at least one light source to encapsulate light sources and also to control characteristics of light delivery from the light sources as light passes through the light transmissive layers.

### TECHNICAL FIELD

The present disclosure relates to illumination devices, and more particularly to thin illumination devices utilizing light management films or devices.

### BACKGROUND

Illumination devices that use light management devices or guides are know in the art in numerous applications. Such devices include a light source and some light management device, such as glass or other light conductive medium to guide the light produced by the light source in a desired manner. Such devices may be used, in particular, to attempt to provide illumination with minimal space utilization particularly in the case of thin light guides or light management devices. Known light devices and fixtures used primarily for providing illumination, however, typically utilize bulky housings containing lighting devices such as incandescent light bulb fixtures or similar lighting devices. In particular applications such as automobile lights, for instance, these known illumination devices utilize a relatively large amount of space.

Some known illumination devices, which attempt to save space, have utilized a glass substrate having a number of arrayed holes. Additionally, the devices include an array of light emitting diode (LED) chips for lighting devices arranged over the array of holes to allow connection wires to connect through the holes to the LED chips. Such devices are affixed to a rear windowpane of glass of an automobile with an adhesive tape to provide a rear stop light for the automobile. Although each of the chips are known to be further covered individually by a covering of transparent resin material, the wires connecting the LED chips to the power source in such devices are run on an opposite side of the substrate, thus requiring the holes in the substrate. Furthermore, the device is typically affixed with a double-sided adhesive tape to bring the device in proximity to a surface of the automobile window.

### SUMMARY

According to an example, an illumination device is disclosed including a substrate; at least one conductive region disposed on the substrate; at least one light source disposed on a surface of the substrate and electrically coupled to the at least one electrically conductive region, and at least one light transmissive layer disposed on the substrate and the at least one light source that encapsulates the at least one light source and at least a portion of the at least one conductive region.

According to another example, a method for making an illumination device is disclosed. The method includes disposing at least one electrically conductive material on a surface of a substrate; disposing at least one light source on the surface of a substrate and electrically coupled with the at least one electrically conductive material; and disposing a light transmissive layer on the light device circuit and at least a portion of the surface of the substrate to encapsulate the at least one light source and at least a portion of the electrically conductive material.

### BRIEF DESCRIPTION OF THE DRAWINGS

FIG. 1 is a side view of an example of a disclosed illumination device.

FIG. 2 is an exploded side view of the device of FIG. 1.

FIG. 3 is a side view of another example of a disclosed illumination device.

FIG. 4 is an exploded side view of the device of FIG. 3.

### DETAILED DESCRIPTION

The present disclosure features illumination devices and methods for making such devices having thin profiles to provide lighting devices that are thinner and take up less space than lighting devices known in the conventional art. Such illumination devices may be utilized in a wide variety of applications. One such application may be for use in vehicles where space usage is a concern. Additionally, some of the presently disclosed illumination devices include light transmissive adhesive encapsulating light sources where the adhesive also is used to affix the illumination devices to an object, such as a window in a vehicle.

According to other examples, the disclosed subject matter is directed to an illumination device for the interior or exterior lighting of a vehicle or building. Exterior lighting, in particular, may include illuminated signs, sometimes referred to as “light boxes.” Illuminated signs are often used to enhance the presentation of images and/or text. Examples of illuminated signs can be found in airports, mass-transit stations, shopping malls and other public places, for example. The signs typically include an enclosure having an illuminated face over which a graphic (including images and/or text) is located. The disclosed illumination devices may be used to effect such types of illuminated signs by including at least one light source and a light transmissive device, with the device being either flat, at least substantially flat, or curved.

As used herein, the term “vehicle” is defined broadly as a means of carrying or transporting something. Types of vehicles which may utilize the illumination devices disclosed herein include, by way of non-limiting example, automobiles, trucks, buses, trains, recreational vehicles, boats, aircraft, motorcycles, and the like.

As also used herein, the term “light source” means any solid state lighting device, including, by way of non-limiting example, LEDs, fluorescent or incandescent lamps, electroluminescent lights, and other similar light sources.

As used herein, the term “light transmissive layer” means any material that transmits or alters transmission properties of visible light. Non-limiting examples of altering properties include reflection, refraction, dispersion, diffraction, and interference.

The illumination devices disclosed herein provide lighting for use in vehicles or buildings that are thinner, more efficient, evenly illuminating, and aesthetically attractive.

It is noted here that, unless otherwise noted, all parts, percentages, and ratios reported in examples described in this disclosure are on a weight basis.

When terms such as “above”, “upper”, “atop”, “upward”, “beneath”, “below”, “lower” and “downward” are used in this application to describe the location or orientation of components in an illumination device, these terms are used merely for purposes of convenience and assuming that the viewing face of the illumination device is horizontal and is viewed from above. These terms are not meant to imply any required orientation for the completed illumination device or for the path taken by supplied or ambient light in actual use of the completed device.

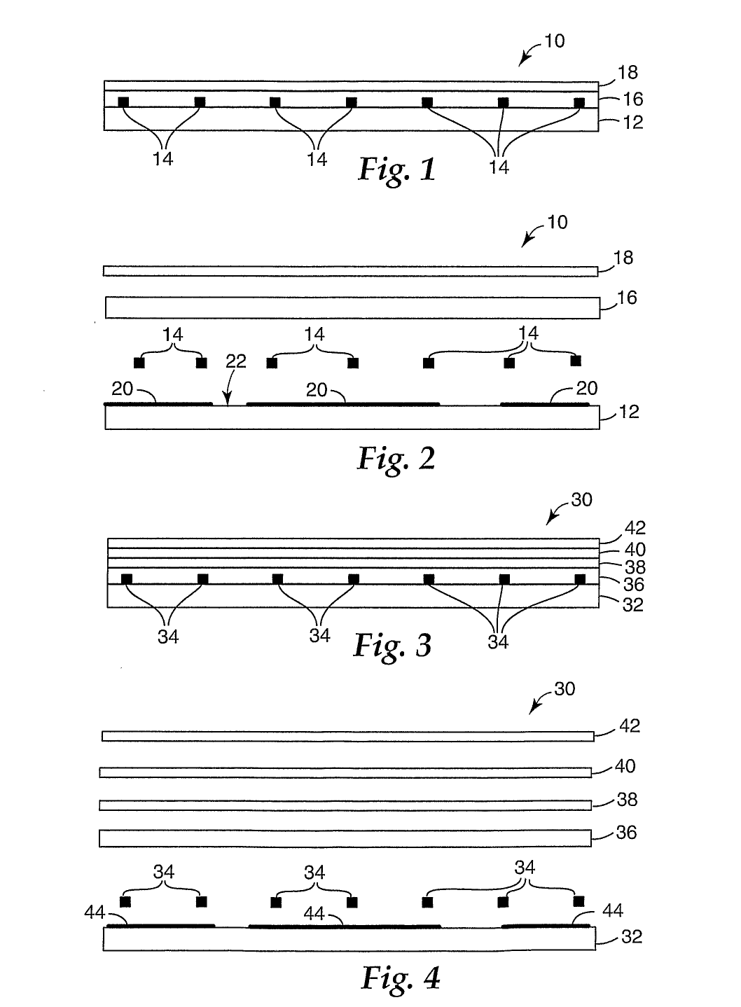

FIG. 1 illustrates an example of an illumination device 10 according to the present disclosure. Device 10 is shown having a substrate 12, one or more light sources 14, a light transmissive layer 16 disposed over the substrate and encapsulating the light sources, and further optional light transmissive devices 18 if desired. In one example, the substrate 12 may be an electrical insulator such as a glass, glass epoxy, clear polyester, or similar insulator. In further examples, the substrate 12 may also be configured to be flexible or rigid. Moreover, the substrate 12 can be configured to be light transmissive and have either transparent, translucent, diffusive, refractive, or reflective properties. As an example, reflector materials impart various qualities to the light, such as color or reflective properties (i.e., mirror). Reflector materials may be mirror films, opaque films or other materials capable of light reflection. The substrate 12 can be a predominantly specular, diffuse, or combination specular/diffuse reflector, whether spatially uniform or patterned. In some cases, the substrate 12 can be made from a stiff metal substrate with a high reflectivity coating, or a high reflectivity film laminated to a supporting substrate. Suitable high reflectivity materials include Vikuiti™ Enhanced Specular Reflector (ESR) multilayer polymeric film available from 3M Company; a film made by laminating a barium sulfate-loaded polyethylene terephthalate film (2 mils thick) to Vikuiti™ ESR film using a 0.4 mil thick isooctylacrylate acrylic acid pressure sensitive adhesive, the resulting laminate film referred to herein as “EDR II” film; E-60 series Lumirror™ polyester film available from Toray Industries, Inc.; porous polytetrafluoroethylene (PTFE) films, such as those available from W. L. Gore & Associates, Inc.; Spectralon™ reflectance material available from Labsphere, Inc.; Miro™ anodized aluminum films (including Miro™ 2 film) available from Alanod Aluminum-Veredlung GmbH & Co.; MCPET high reflectivity foamed sheeting from Furukawa Electric Co., Ltd.; and White Refstar™ films and MT films available from Mitsui Chemicals, Inc.

Yet in further examples, the substrate 12 may also be configured to be thermally conductive or include at least thermally conductive regions or portions. Additionally, the substrate may include thermally conductive vias (not shown) to transport heat from heat producing elements, such as the one or more light sources 14.

The substrate 12 may also include electrically conductive regions consisting of electrical conductors for electrically coupling the light sources 14 to a power source. Examples of such electrically conductive regions include electrically conductive material disposed onto the substrate 12 to provide electrical coupling of the light sources 14. The material could include, but is not limited to, conductive ink, paint, adhesive, indium tin oxide, conductive polymers, or metals such as copper, silver, gold, aluminum, palladium, titanium, or any other suitable electrically conductive material. It is further noted that the conductive regions can be formed on the substrate 12 by printing, spraying, blade coating, roll coating, vapor coating, plasma coating, electro-plating, or electroless plating as examples.

Additionally, the conductive regions can be formed in selected patterns by screen printing, shadow masking, photolithography, etching, ablating, or laser induced thermal imaging, as examples. The patterned conductive regions may be configured to form circuitry that drives the light source devices 14 as desired. Circuit configurations may include parallel busses to which the devices 14 are connected across, series circuit connections, an array of parallel buses, an array of series circuits, arrays of series circuits connected by parallel buses, arrays of parallel buses connected by series circuits, an array of individual circuits, or combinations of any of these. In particular, the lights sources 14 are electrically coupleable to a power supply (not shown) using patterned conductive regions or circuits disposed on a surface of the substrate 12 on which the light sources 14 are also disposed.

The light sources 14 may be one or more light emitting diodes (LEDs) arranged in an array, but are not limited to such. Examples of LEDs that may be used include LEDs of various colors such as white, red, orange, amber, yellow, green, blue, purple, or any other color of LEDs known in the art. The LEDs may also be of types that emit multiple colors dependent on whether forward or reverse biased, or of types that emit infrared or ultraviolet light. Furthermore, the LEDs may include either packaged LEDs or nonpackaged LEDs, which may be mounted directly on the substrate 12.

The light transmissive layer 16 may be any transparent, translucent, partially reflective (such as a controlled or selective transmissive reflective materials and films such as disclosed in U.S. Pat. No. 6,208,466, which is incorporated by reference herein), refractive, diffusive, or any other property effective for the transmission of at least a portion of the light emanating from the light sources 14 through the layer 16 in some manner. In one example, the light transmissive layer 16 is effective for evenly distributing the light emitted by the light sources 14. One skilled in the art will appreciate that any number of optical layers, devices or films may be appropriate for use in the illumination devices described herein, such as the light transmissive layer 16. In particular, the light transmissive layer 16 may also be a light transmissive adhesive, glass or glass epoxy as will be described later.

The light transmissive layer 16 may also be diffusive and include any suitable diffuser film or plate. For example, layer 16 can include any suitable diffusing material or materials. In some embodiments, the layer 16 may include a polymeric matrix of polymethyl methacrylate (PMMA) with a variety of dispersed phases that include glass, polystyrene beads, and CaCO₃ particles. Exemplary diffusers can include 3M™ Scotchcal™ Diffuser Film, types 3635-30 and 3635-70, available from 3M Company, St. Paul, Minn. Additionally, it is contemplated that the diffuser may include a graphic, which may feature images and/or text, such as for use as a sign, as an example. The light transmissive layer may also include a reflective polarizer. Any suitable type of reflective polarizer may be used, e.g., multilayer optical film (MOF) reflective polarizers, diffusely reflective polarizing film (DRPF), such as continuous/disperse phase polarizers, wire grid reflective polarizers, or cholesteric reflective polarizers.

Both the MOF and continuous/disperse phase reflective polarizers rely on the difference in refractive index between at least two materials, usually polymeric materials, to selectively reflect light of one polarization state while transmitting light in an orthogonal polarization state. Some examples of MOF reflective polarizers are described in co-owned U.S. Pat. No. 5,882,774 (Jonza et al.). Commercially available examples of MOF reflective polarizers include Vikuiti™ DBEF-D200 and DBEF-D440 multilayer reflective polarizers that include diffusive surfaces, available from 3M Company.

Examples of DRPF useful in connection with the present disclosure include continuous/disperse phase reflective polarizers as described, e.g., in co-owned U.S. Pat. No. 5,825,543 (Ouderkirk et al.), and diffusely reflecting multilayer polarizers as described, e.g., in co-owned U.S. Pat. No. 5,867,316 (Carlson et al.). Other suitable types of DRPF are described in U.S. Pat. No. 5,751,388 (Larson).

Some examples of wire grid polarizers useful in connection with the present disclosure include those described, e.g., in U.S. Pat. No. 6,122,103 (Perkins et al.). Wire grid polarizers are commercially available from, inter alia, Moxtek Inc., Orem, Utah.

Some examples of cholesteric polarizers useful in connection with the present disclosure include those described, e.g., in U.S. Pat. No. 5,793,456 (Broer et al.), and U.S. Patent Publication No. 2002/0159019 (Pokorny et al.). Cholesteric polarizers are often provided along with a quarter wave retarding layer on the output side so that the light transmitted through the cholesteric polarizer is converted to linearly polarized light.

FIG. 2 is an exploded side view of the device 10 of FIG. 1 and like reference numerals refer to the same elements as shown in FIG. 1. As may be seen in FIG. 2, the substrate 12 includes one or more electrically conductive regions 20, which are disposed on a top surface 22 of the substrate 12. As was described previously, the electrically conductive regions 20 may be constructed with various processes such as screening, etching, and other known methods for disposing conductive material on a substrate.

According to a first constructed example using screening, for example, an electrically conductive region was prepared as follows. A 51 cm×61 cm 230-mesh screen (91 threads per cm), commercially available from Ryan Screen Printing Supplies, St. Louis, Mo., was created to using a common photo developing process, available through Vomela Company, St. Paul, Minn. Using a 70-durometer squeegee and moderate to light printing pressure, an electrically conductive ink was flooded to fill the screen and then the screen was pressed into contact with a 5-mil (127 micrometers) transparent polyester sheet as the substrate 12 (25 cm×25 cm). The electrically conductive ink transferred from the screen to the sheet in the pattern of the open area on the screen. Silver conductive ink, as an example, such as the trade designation “1660-136” from Ercon, Inc., Wareham, Mass., was screen printed onto the polyester sheet to form opposing bus rails. In this example, ten (10) separate rails were printed. The rails printed were 0.25 mm, 0.50 mm, 0.75 mm, 1.00 mm, 1.25 mm, 1.50 mm, 1.75 mm, 2.00 mm, 2.25 mm and 2.50 mm wide, each with a gap of 31 mils (0.79 mm).

White light LEDs, obtained as part number “QTLT601C1WTR” from Fairchild Semiconductor Corporation, Portland, Me., were then bonded in gaps in the buss rails using a silver-filled conductive adhesive, obtained under the trade designation “MD-140”, from Lord Corporation, Cary, N.C., and cured for 30 minutes at 185° F. (85° C.). The LEDs were illuminated using a milliamp current supply, commercially obtained under model number “6214a” from Hewlett Packard Company, Palo Alto, Calif. The resistance of each printed rail was measured using a 3466A Digital Multimeter from the Hewlett Packard Corporation. The resistance as a function of rail width and screen mesh is listed in Table 1:

TABLE 1

| | Resistivity 20 mOhm | Resistivity 20 mOhm |
|---|---|---|
| Line Width (mm) | f.s./cm 230 mesh | f.s./cm 305 mesh |
| 0.25 | 2.39 | 2.28 |
| 0.50 | 1.35 | 1.31 |
| 0.75 | 0.95 | 0.97 |
| 1.00 | 0.79 | 0.76 |
| 1.25 | 0.65 | 0.62 |
| 1.50 | 0.62 | 0.57 |
| 1.75 | 0.57 | 0.51 |
| 2.00 | 0.51 | 0.44 |
| 2.25 | 0.44 | 0.38 |
| 2.50 | 0.38 | 0.33 |

As would be expected, the light intensity of each LED was inversely proportional to the distance from the power source.

As a second constructed example, the first example above was repeated, wherein the LEDs were connected by parallel conductive circuit traces as the electrically conductive regions 20 on the substrate 12. Multiple circuits were created side by side.

The multiple circuits were all connected together in parallel by a conductive bus. A 2-dimensional array of uniformly illuminated LEDs was obtained using this construction.

In still a third constructed example, the pattern of the first example above was constructed wherein the conductive ink circuit was replaced by patterned copper on flexible circuit material as the substrate, commercially available from 3M Company. Conductive circuit traces were patterned in a number of series or parallel circuits that were connected to a parallel bus to provide a two dimensional array for uniform area illumination with LEDs applied by traditional soldering technology. In this third example, it is noted that a 3M ESR film was placed beneath the circuit as the substrate, and a translucent diffuser film spaced at a nominal distance above the circuit as the light transmissive layer 16 to produce a diffuse light source. It is noted that the nominal distance spacing is not illustrated in FIGS. 1 and 2.

Turning back to FIG. 2, this figure also illustrates each of the light source devices 14, which are disposed on the substrate 12 and electrically coupled to the electrically conductive regions 20. The light source devices, such as LEDs, may be bonded to the substrate and electrically coupled to regions 20 using any number of various suitable processes, such as using electrically conductive adhesive or traditional soldering techniques as described previously in the examples above. One skilled in the art will appreciate, however, that other suitable methods and processes may be used to dispose or bond the light source devices 14 to substrate 12.

After the light sources 14 are affixed to the substrate 12, at least one light transmissive layer 16 may be applied directly to the top surface 22 of the substrate 12. Application of layer 16 may serve to encapsulate the light sources 14, as well as the conductive regions 20. However, as noted above in the second and third examples, a nominal spacing between layer 16 and substrate 12 may also be effected, such as using spacers disposed between the substrate 12 and the layer 16.

The light transmissive layer 16 may also impact other functionality, such as mounting onto fixtures, using adhesive compositions. Examples include pressure sensitive adhesives (PSAs), cast adhesive, such as polyurethanes, acrylates or urethane acrylates such as those obtained under the trade designation “VHB Tape” from 3M Company. As an example, a fourth device with a structure similar to the device 10 in FIG. 2 was constructed by first applying an LED circuit (i.e., conductive regions 20 and light sources 14) of the first constructed example (see above) to a sheet of glass as the substrate 12. A layer of adhesive base syrup was next applied over the circuit and the top surface 22 of the substrate 12.

For purposes of this example only, and not by way of limitation, the adhesive base syrup was prepared by manually mixing in a 1-pint (0.47 liter) glass jar at room temperature, 307.5 grams isooctyl acrylate (IOA), 12 grams of acrylic acid (AA), 6.3 grams of CTB (a 25% by weight solution of carbon tetrabromide in IOA and obtained from; Epichem Inc. Allentown, Pa.), and 0.16 grams a first photoinitiator (PI1), which is commercially available under the trade designation “Darocur 1173”, from Ciba Specialty Chemicals, Tarrytown, N.Y. The mixture was loosely covered and purged with nitrogen for 10 minutes, after which it was partially polymerized by exposure to two 15 watt blacklight bulbs, until the viscosity was approximately 1,000 centipoise (1 Pas). The ultraviolet radiation and nitrogen purge were discontinued and 1.88 grams of a second photoinitiator (PI2, which is commercially available under the trade designation “Lucerin TPO”, from BASF Corporation, Florham Park, N.J.) was added, the jar sealed and then placed on a roller mill for 30 minutes to produce the adhesive base syrup. Next, 35.2 grams of the base syrup was manually mixed with 1.0 grams of 1,6-hexanediol diacrylate (HDDA) for 2 minutes in a 250 milliliter glass jar. The resulting adhesive syrup had a ratio of 93.2:3.9:2.8 by weight of IOA:AA:HDDA, respectively.

After the layer of adhesive base syrup is applied over the circuit and the top surface 22 of the substrate 12, a 25 micrometer thick silicone coated polyester release liner, obtained under the trade designation “T-10” from CP Films Company, Martinsville, Va., is then applied over the adhesive base syrup. The assembly was passed through a bar coater set to a gap of approximately 1 millimeter and then cured by irradiating with two 40 watt blacklight bulbs at a distance of about 4 inches (10.2 cm) for about 10 minutes. After curing of the adhesive base syrup to form the light transmissive layer 16, the release liner was removed.

It is noted that the above example yields an illumination device 10 where the light transmissive layer 16 is also a light transmissive adhesive that may be used to affix the device to a surface as an appliqué, for example. This device could be affixed to glass, such as a window in an automobile, for example.

In a further example based on the fourth example above, the optional light transmissive layer 18 shown in FIGS. 1 and 2 could be added, such as another layer of glass affixed with the adhesive base layer (light transmissive layer 16). Additionally, the LEDs (light source 14) may be illuminated using a milliamp current supply, commercially obtained under model number “6214a” from Hewlett Packard Company.

Either of light transmissive layers 16 or 18 may also be configured to provide illumination devices having a light distribution angle that is large (greater than 90 degrees), such as for use as ambient illumination sources. Similarly, the layers 16, 18 can be configured to provide light distribution with a distribution angle that is small (less than 90 degrees), such as for functional illumination (e.g., reading lights, sspotlights egress lighting, etc.).

Light extraction from the one or more light sources 14 may also be enhanced by encapsulating or coating the light sources 14 in order to improve extraction efficiency at the surface of an LED, for example, by defeating total internal reflection at the LED/light transmissive interface. This may be accomplished by providing uniform light distribution by guiding light within the encapsulating material or coating using total internal reflection. Furthermore, diffuse light distribution from within the medium by reflection or scattering may be produced by incorporating nanoparticles, glass microspheres, or Bragg gratings, as examples. Additional directed light distribution from within the medium may be achieved using prismatic or microstructured surfaces, lenslet arrays, shaped ribs, or random chaotic surface patterns, as examples.

FIG. 3 illustrates a further example of a multi-layered illumination device 30 including a substrate 32, light sources 34, a light transmissive layer 36, two layers of brightness enhancement films 38 and 40, and a cover 42. The two brightness enhancement film layers 38, 40 function to redirect and recycle light to increase the brightness of the light from the illumination device. Examples of such films include commercial one-dimensional (linear) prismatic polymeric films such as Vikuiti™ brightness enhancement films (BEF), Vikuiti™ transmissive right angle films (TRAF), Vikuiti™ image directing films (IDF), and Vikuiti™ optical lighting films (OLF), all available from 3M Company, as well as conventional lenticular linear lens arrays. When these one-dimensional prismatic films are used as light extraction films in the disclosed direct-lit backlights, it is usually desirable for the prismatic structured surface to face the light source.

Further examples of light enhancement films where the structured surface has a two-dimensional character, include cube corner surface configurations such as those disclosed in U.S. Pat. Nos. 4,588,258 (Hoopman), 4,775,219 (Appeldorn et al.), 5,138,488 (Szczech), 5,122,902 (Benson), 5,450,285 (Smith et al.), and 5,840,405 (Shusta et al.); inverted prism surface configurations such as described in U.S. Pat. Nos. 6,287,670 (Benson et al.) and 6,280,822 (Smith et al.); structured surface films disclosed in U.S. Pat. No. 6,752,505 (Parker et al.) and U.S. Patent Publication No. 2005/0024754 (Epstein et al.); and beaded sheeting.

As illustrated, the cover 42 is placed atop the entire construction. In an example, the cover 42 is a transparent or translucent polymeric material. In further embodiments, the cover 42 may be a light management device, such as a diffuser layer.

FIG. 4 illustrates a further exploded view of the illumination device 30 of FIG. 3. As may be seen in this view, the device 30 includes conductive regions 44 disposed on the substrate 32, similar to the conductive regions 20 in the example of FIGS. 1 and 2. Furthermore, similar to the example of FIGS. 1 and 2, the example shown in FIG. 4 is constructed in a similar manner starting with the substrate 32 and adding the conductive regions 44, light sources 34, and light transmissive layer 36, brightness enhancement films 38 and 40, and cover 42.

Further constructed examples are described in the following text.

In a fifth constructed example, the first constructed example discussed previously was repeated wherein a light tape was coated with a thin, uniform coating of urethane as follows. A curable two part polyurethane composition was prepared by mixing 1.0 part of (A), which was 99.7 parts of 5901-300 polyol from Inolex Chemical Company, Philadelphia Pa., a polyester polyol cross-linked with dipropylene glycol phthalate adiapate and having a hydroxyl number of 305, and 0.3 parts of dibutyl tin dilaurate catalyst, and 1.15 parts of (B), which was 100 parts of Desmodur N-100 aliphatic polyisocyanate based on hexamethylene diisocyanate and having an equivalent weight of 191, available from the Bayer Corporation in Pittsburgh Pa. The urethane served to encapsulate and protect the LEDs as the light transmissive layer 36, and also coupled light from the LEDs into the multilayer structure (38, 40, 42) by providing a medium with a refractive index more closely matched than the LEDs would be in air.

In yet a sixth constructed example, the first constructed example 1 was repeated, wherein the 5 mil (127 micrometer) clear polyester as light transmissive layer 36 was replaced with an enhanced specular reflector film, commercially available under the trade designation “Vikuiti ESR” (ESR) from 3M Company, provided an illuminated mirror-like film.

In still a seventh constructed example, a protective sheet of ESR film was laminated over the LEDs as layer to provide a reflective upper surface in addition to using an ESR film for the substrate 32 to provide a reflective lower surface. The resulting structure provided uniform edge illumination along the length of the tape structure with minimal light emission from the upper and lower mirror surfaces. This example could also be used without the multilayer structure of FIG. 3 and instead with the structure of FIGS. 1 and 2.

In an eighth constructed example, a brightness enhancement film (BEF) was disposed on the substrate (either 32 or 12) as the light transmissive layer 16 or 36. The BEF obtained under the trade designation “Vikuiti BEF” (BEF) from 3M Company. Brightness of the light emitted from the surface of the light sources 34 (or 14) was increased through a controlled viewing angle.

In a ninth constructed example, the eighth constructed example was repeated, and the BEF film on the upper surface was further laminated, in an orthogonal orientation, with another layer of BEF (i.e., layer 38). Brightness of the light emitted from the surface of the light sources 34 was increased by further controlling the viewing angle.

In a tenth constructed example, the third example discussed previously, was repeated, where a BEF (e.g., 38) was laid over the diffuser film (i.e., 16 or 36) to further control brightness and emission angle. A second BEF (e.g., 40) was oriented orthogonally over the first BEF to provide an even brighter and more uniform directional light source.

In an eleventh constructed example, the tenth example above was repeated, wherein a uniform, directional area light source was created by formation of an optical cavity having the ESR LED circuit from Example 10 on the back surface to act as a reflector, and BEF, alone or in combination as described in Example 1, placed at some distance away, and parallel to, the ESR surface, to create a cavity that will cause light within the cavity to reflect between the surfaces repeatedly until it can escape the cavity at the preferred angles permitted by the BEF film, thereby increasing uniformity and brightness in the viewing direction.

In a twelfth constructed example, the light strip as described in the first constructed example was prepared. The process described in EP 0 392 847, the content of which is incorporated by reference, was used to prepare a molded three-dimensional article with lights in registration to the molded urethane elements. A porous mold was prepared with lights from the strip in the first example in registration to the cavities in the mold. A transparent polyolefin film was formed into the mold with heat and vacuum as described. The film was an integral part of the molded article. A curable two part polyurethane composition was prepared by mixing 1.0 part of (A), which was 99.7 parts of 5901-300 polyol from Inolex Chemical Company, Philadelphia Pa., a polyester polyol cross-linked with dipropylene glycol phthalate adiapate and having a hydroxyl number of 305, and 0.3 parts of dibutyl tin dilaurate catalyst, and 1.15 parts of (B), which was 100 parts of Desmodur N-100 aliphatic polyisocyanate based on hexamethylene diisocyanate and having an equivalent weight of 191, available from the Bayer Corporation, Pittsburgh, Pa. The transparent urethane composition was poured onto the film that was formed into a warm mold (80° C.). Before the urethane cures to a solid, the light strip was applied to the liquid urethane in registration to the cavities in the mold. Pressure is applied to the backside of the light tape with a roller to make the molded element as smooth as possible. The urethane was allowed to cure for 5 minutes and then de-molded. It is noted that the bus bars on the light strip were not totally covered by the urethane at one end so that electrical connection of a power source to the bus bars can be effected.

According to a thirteenth constructed example, the twelfth example described above was repeated, wherein 0.2% glass bubbles, obtained under the trade designation “K25 Scotchlite Glass Bubbles” from 3M Company, were added to the urethane to create a diffusion encapsulation material.

According to a fourteenth constructed example, the strip of LEDs from the first example was cut into a 2.5 cm×14.0 cm pieces along the length of the bus bars. Glass was cut into 100 mm×125 mm pieces. The glass was automotive grade solar glass that is 2 mm thick and was obtained from Viracon/Curvlite Inc., Owatonna, Minn. Polyvinylbutyral (PVB) film was also cut into 100 mm×125 mm pieces. The PVB film is 375 microns thick Saflex RK11 and is supplied by Solutia Inc., St. Louis, Mo. The film had a texture on one surface to facilitate air release. The PVB film had a textured surface and was applied to the glass surface to facilitate air release. A lay-up was prepared that included a layer of glass, a layer of Saflex RK-11, a strip of light tape from Example 1, a layer of Saflex RK-11 where 3 mm holes were punched in the sheet in registration with the LED pattern, a third sheet of Saflex RK-11 and a second layer of glass.

The corners of the samples were taped with white “471” tape from 3M Company. To hold the lay-up in place, a 25 micron thick silicone coated polyester release liner obtained under the product designation “T1” from CP Films, Martinsville, Va., was cut to 125 mm×275 mm, and was wrapped around the stack. The stack wrapped with the liner was inserted into a vacuum-sealing bag. Air was evacuated from the bag and it was sealed using a common vacuum food storage device. The sealed bag was placed into an autoclave that controls temperature and pressure. The temperature and pressure were adjusted according to the following schedule shown in TABLE 2.

TABLE 2

| Time | Pressure | Temperature |
|---|---|---|
| (minutes) | (KPa) | (degrees C.) |
| 0 | 345 | 22.2 |
| 10 | 689 | 57.2 |
| 20 | 1103 | 107.2 |
| 30 | 1103 | 137.7 |
| 40 | 1103 | 137.7 |
| 50 | 1103 | 137.7 |
| 60 | 1103 | 137.7 |
| 70 | 1069 | 123.9 |
| 80 | 1000 | 107.2 |
| 90 | 965 | 90.6 |
| 100 | 862 | 73.9 |
| 110 | 862 | 61.1 |
| 120 | 103 | 37.8 |

The sample was removed from the autoclave and the protective liners and tapes were removed. The samples were cleaned with glass cleaner. The samples were clear with no air entrapment. This was a typical cycle for manufacturing safety glass. Unique effects were observed when various films were applied over the top surface of the lighted glass. The combination of the films created unique effects. The films included BEF, DBEF, ESR, diffusion films, and translucent tinted films.

The illumination devices described herein are suitable for use in a variety of applications for illuminating surfaces, such as the interior or exterior surfaces of vehicles as an example. In addition, the disclosed illumination devices may be used in other applications such as interior or exterior lighting for buildings, and illuminated signs as was mentioned previously.

Illuminated signs, sometimes referred to as light boxes are often used to enhance the presentation of images and/or text. Examples of Illuminated signs can be found in e.g., airports, mass-transit stations, shopping malls and other public places. The signs typically include an enclosure having an illuminated face over which a graphic (including images and/or text) is located. In the context of devices described herein, a graphic may be placed on or made a part of light cover structures 16, 18, 36, 38, 40 and 42, and in some embodiments may be formed as part of a reflective surface on a substrate 12, 32.

The illumination devices described herein are suitable for use on any surface of a vehicle traditionally provided with lighting such as overhead dome lighting, glove box lighting, floor lighting, map lights, mirror lights, decorative lights, rear window brake lights, and the like. In addition, the illumination devices described herein are suitable for providing lighting in places where prior art lighting systems would be difficult or impractical. Due to the thin construction of the devices and the configuration of the light source, the illumination devices of the present disclosure may be installed in confined spaces.

As one skilled in the art will appreciate, varieties of combinations of the components described herein are possible to provide suitable illumination devices. For example, it is anticipated that the disclosed substrates of the present disclosure may be formed from other flexible materials, as well as the conductive regions being constructed from flexible materials. For example, copper etched circuits on polyester teraphthalate (PET) or polyamide such as those obtained under the trade designations “Flexible Circuits” from 3M Company. Transparent conductive regions may also be prepared by pattern sputter coating indium tin oxide (ITO) on a polyester film, obtained from CP Films, Inc., Martinsville Va. Another option for creating conductive region patterns is to laser ablate or etch the patterns from a full sheet of ITO coated polyester.

The protective cover (e.g., 42) may be formed from other transparent conformable tapes, such as cast polyvinyl chloride films obtained under the trade designation “Scotchcal” from 3M Company, St. Paul, Minn. Furthermore, to diffuse or re-direct the intensity from the LED source, the film may be textured to create a diffuser, structured or microstructured, or, to create other lighting effects, may be colored, or employ other optically modified films, such as Multilayer Optical Films (MOF), obtained under trade designations such as “Vikuiti” and “Photonics Filter Film” from 3M Company. Likewise, there are other versions of brightness enhancement films that may be laminated to the surface of the light tape alone, or in combination, to control brightness and viewing angle, each according to its special optical properties.

The protective cover may also consist of coatings such as urethane, silicone, acrylate, polyvinyl buterol, or other polymers selected for their structural or optical properties. These protective coatings may be used in their basic form, or may incorporate nanoparticles, glass microsphers, etc to enhance diffusion, uniformity, modify color, etc.

It is further contemplated that the illumination devices of the present invention may subsequently be molded into various illuminated artifacts, including, but not limited to, buttons, coffee cups, traffic delineators, window housings, body side moldings, bumper covers, furniture, countertops, toilet seats, shower doors, and the like.

It is still further contemplated that the disclosed illumination devices may alternately be coated with other suitable materials to protect the LEDs and provide index matching, including acrylic resins, polyvinyl butyral polymer, polyolefin resins, epoxy resins or silicones resins, etc. The resin could be filled with diffusing components such as glass beads, silica particles, fibers, or pigments.

While the illumination device depicted in the figures shows the devices as substantially planar articles, it should be appreciated that the devices may be constructed as a curved article. As one skilled in the art will appreciate, various combinations of the light management devices could be utilized with various configurations of light sources to produce an illumination device. Further, as one skilled in the art would appreciate, the entire structures shown in FIGS. 1-4 may be encased in a housing.

The optical qualities of the illumination devices described herein may be further enhanced by the use of additional light management films or layers. Suitable light management devices for use in the illumination devices described herein include, light control films for glare and reflection management, prismatic brightness enhancement films, diffuser films, reflective films, reflective polarizer brightness enhancement films, reflectors and turning films

One skilled in the art will also appreciate that light sources used in the devices described herein can be provided in a variety of forms. The light source may be, for example, a linear or non-liner array of one or more LEDs, or other form of light source such as fluorescent or incandescent lamps, electroluminescent lights and the like. In other examples, a matrix or grid of LED lights may be used. In some examples, the light may be colored. In still other examples there may be more than one light source provided in the illumination device. The light source may include a dimmable control, on/off control, color control and the like.

In light of the foregoing, the present disclosure provides illumination devices that are thin, efficient, evenly illuminating, and aesthetically attractive. Additionally, aspects of the disclosed illumination devices afford ease of use, such as easy attachment to surfaces such as automobile windows and other interior or exterior surfaces.

The above-detailed examples have been presented for the purposes of illustration and description only and not by limitation. It is therefore contemplated that the present disclosure cover any additional modifications, variations, or equivalents that fall with in the spirit and scope of the basic underlying principles disclosed above and the appended claims.

What is claimed is:

1. An illumination device comprising:
a substrate;
at least one conductive region disposed on the substrate;
at least one light source disposed on a surface of the substrate and electrically coupled to the at least one electrically conductive region, and
at least one light transmissive layer disposed on the substrate and the at least one light source that encapsulates the at least one light source and at least a portion of the at least one conductive region.

2. The illumination device as defined in claim 1, wherein the at least one light transmissive layer is one of transparent or translucent.

3. The illumination device as defined in claim 1, wherein the at least one light transmissive layer is a polarizing film.

4. The illumination device as defined in claim 1, wherein that at least one light transmissive layer is a light diffuser.

5. The illumination device as defined in claim 1 wherein the at least one light transmissive layer is composed of a light transmissive adhesive.

6. The illumination device as defined in claim 5 further comprising:
a second light transmissive layer affixed to a surface of the first light transmissive layer with the light transmissive adhesive.

7. The illumination device as defined in claim 6, wherein the substrate and the second light transmissive layers are one of glass or glass epoxy.

8. The illumination device as defined in claim 1, wherein the substrate is configured to be light transmissive.

9. The illumination device as defined in claim 7, wherein the light transmissive substrate is at least one of transparent, translucent, refractive, diffractive, reflective, or diffusive.

10. The illumination device as defined in claim 1 wherein the substrate is configured to be thermally conductive.

11. The illumination device as defined in claim 1, wherein the at least one conductive region comprises at least one of electrically conductive ink, paint, adhesive, indium tin oxide, and a conductive polymer.

12. The illumination device as defined in claim 1, wherein the at least one conductive region comprises a metal conductor comprised of least one of copper, silver, gold, aluminum, palladium, and titanium.

13. The illumination device as defined in claim 1 wherein the at least one conductive region is comprised of an electrical conductor that is light transmissive.

14. The illumination device as defined in claim 13, wherein the electrical conductor is one of transparent and translucent.

15. The illumination device as defined in claim 1 wherein the substrate is flexible.

16. The illumination device as defined in claim 1 wherein the illumination device contains at least two light management devices.

17. The illumination device as defined in claim 1, including at least two light transmissive layers including a first transmissive layer disposed on the substrate and the at least one light source and a second transmissive layer disposed on the first transmissive layer.

18. The illumination device as defined in claim 17, wherein at least one of the light transmissive layers is one of transparent, translucent, refractive, diffractive, diffusive, or reflective.

19. The illumination device as defined in claim 17, wherein at least one of the light transmissive layers is a brightness enhancing film (BEF).

20. The illumination device as defined in claim 17, further comprising a cover disposed on the second transmissive layer.

21. The illumination device as defined in claim 20, wherein the cover is one of transparent, translucent, refractive, diffractive, diffusive, or reflective

22. The illumination device as defined in claim 1 wherein the substrate is substantially planar in shape.

23. The illumination device as defined in claim 1, wherein the substrate is curved.

24. The illumination device of claim 1 in combination with a motor vehicle.

25. The illumination device of claim 1 in combination with a building.

26. The illumination device of claim 1 in combination with an illuminated sign.

27. A method for making an illumination device comprising:
disposing at least one electrically conductive material on a surface of a substrate;
disposing at least one light source on the surface of a substrate and electrically coupled with the at least one electrically conductive material; and
disposing at least one light transmissive layer on the electrically conductive
material and at least a portion of the surface of the substrate to encapsulate the at least one light source and at least a portion of the electrically conductive material.

28. The method as defined in claim 27, wherein the at least one light transmissive layer is one of transparent or translucent.

29. The method as defined in claim 27, wherein the at least one light transmissive layer is a polarizing film.

30. The method as defined in claim 27, wherein that at least one light transmissive layer is a light diffuser.

31. The method as defined in claim 27 wherein the at least one light transmissive layer is composed of a light transmissive adhesive syrup.

32. The method as defined in claim 31 further comprising:
applying a release liner on a surface of the light transmissive adhesive syrup;
curing the light transmissive adhesive syrup;
removing the release liner; and
disposing a second light transmissive layer on the cured light transmissive adhesive syrup.

33. The method as defined in claim 32, wherein the substrate and the second light transmissive layer are one of glass or glass epoxy.

34. The method as defined in claim 27, wherein the substrate is configured to be light transmissive.

35. The method as defined in claim 34, wherein the light transmissive substrate is at least one of transparent, translucent, refractive, diffractive, reflective or diffusive.

36. The method as defined in claim 27 wherein the substrate is configured to be thermally conductive.

37. The method as defined in claim 27, wherein the at least one conductive region comprises at least one of electrically conductive ink, paint, adhesive, indium tin oxide, and a conductive polymer.

38. The method as defined in claim 27, wherein the at least one conductive region comprises a metal conductor comprised of least one of copper, silver, gold, aluminum, palladium, and titanium.

39. The method as defined in claim 27 wherein the at least one conductive region is comprised of an electrical conductor that is light transmissive.

40. The method as defined in claim 39, wherein the electrical conductor is one of transparent and translucent.

41. The method as defined in claim 27 wherein the substrate is flexible.

42. The method as defined in claim 27 wherein the illumination device contains at least two light management devices.

43. The method as defined in claim 27, including at least two light transmissive layers including disposing a first transmissive layer on the substrate and the at least one light source and a disposing a second transmissive layer on the first transmissive layer.

44. The method as defined in claim 43, wherein at least one of the light transmissive layers is one of transparent, translucent, refractive, diffractive, diffusive, or reflective.

45. The method as defined in claim 44, wherein at least one of the light transmissive layers is a brightness enhancing film (BEF).

46. The method as defined in claim 43, further comprising disposing a cover on the second transmissive layer.

47. The method as defined in claim 46, wherein the cover is one of transparent, translucent, refractive, diffractive, diffusive, or reflective

48. The method as defined in claim 27 wherein the substrate is substantially planar in shape.

49. The method as defined in claim 27, wherein the substrate is curved.

50. The method as defined in claim 27, wherein disposing at least one electrically conductive material on the surface of a substrate includes a process selected from the group consisting of printing, spraying, blade coating, roll coating, vapor coating, plasma coating, electro-plating, and electroless plating.

51. The method as defined in claim 27, wherein disposing at least one electrically conductive material on the surface of a substrate includes forming a predefined pattern of conductive material using a process selected from the group consisting of screen printing, shadow masking, photolithography, etching, ablating, and laser induced thermal imaging.
